(19) United States
(12) Patent Application Publication
(10) Pub. No.: US 2024/0355592 A1
(43) Pub. Date: Oct. 24, 2024

(54) UNIFORM PLASMA PROCESSING WITH A LINEAR PLASMA SOURCE

(71) Applicant: Applied Materials, Inc., Santa Clara, CA (US)

(72) Inventors: Vladimir Nagorny, Tracy, CA (US); Rene George, Redwood City, CA (US)

(21) Appl. No.: 18/138,629

(22) Filed: Apr. 24, 2023

(51) Int. Cl. H01J 37/32; G06N 3/084

(52) U.S. Cl. CPC H01J 37/32568; G06N 3/084; H01J 37/32348; H01J 37/32449; H01J 2237/032; H01J 2237/20214

(57) ABSTRACT

A plasma generating component for a process chamber includes a first pair of linear electrodes. Each electrode of the first pair of linear electrodes extends from a first edge of a plasma generating region of the plasma generating component to a second edge of the plasma generating region of the plasma generating component. Electrodes of the first pair of linear electrodes are substantially parallel. The plasma generating component further includes a second pair of linear electrodes, substantially parallel to the first pair of linear electrodes. The plasma generating component further includes a dielectric support to which the first pair of linear electrodes and the second pair of linear electrodes are secured.

### TECHNICAL FIELD

The instant specification relates methods and systems for controlling plasma processing. Specifically, the instant specification relates to uniform plasma processing using a linear plasma source for plasma processing.

### BACKGROUND

Plasma processing is widely used in the semiconductor industry. Plasma can modify a chemistry of a processing gas (e.g., generating ions, radicals, etc.). Plasma can be used in creating new species, without limitations related to some process conditions such as the process temperature. Plasma processing may be used in generating a flux of ions to the wafer with energies from a fraction of an electronvolt (eV) to thousands of eVs. There are many kinds of plasma sources (e.g., capacitively coupled plasma (CCP), inductively coupled plasma (ICP), microwave generated plasma, electron cyclotron resonance (ECR), and the like) that cover a wide operational process conditions ranging from a few mtorr to a few torr.

A common target of a plasma process specification is a high uniformity of the process result (e.g., a uniformity across a wafer up to the very edge of the wafer). For example, process uniformity targets in today's semiconductor manufacturing may include targets around 1%-2% across the whole wafer, with exclusion of 1-3 mm from the edge. These stringent constraints continuously get even firmer as researchers look for new methods for controlling process uniformity and/or finding improvements to existing methods for controlling process uniformity. Different uniformity controlling methods may be effective for some processes and completely useless for others.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

In one aspect of the present disclosure, a plasma generating component for a process chamber includes a first pair of linear electrodes. Each electrode of the first pair of linear electrodes extends from a first edge of a plasma generating region of the plasma generating component to a second edge of the plasma generating region of the plasma generating component. Electrodes of the first pair of linear electrodes are substantially parallel. The plasma generating component further includes a second pair of linear electrodes, substantially parallel to the first pair of linear electrodes. The plasma generating component further includes a dielectric support to which the first pair of linear electrodes and the second pair of linear electrodes are secured.

In another aspect of the present disclosure, a method includes generating a plasma for substrate processing. Generating the plasma includes providing a first voltage to a first electrode of a first pair of linear electrodes. The first electrode extends from a first edge of a plasma generating region to a second edge of the plasma generating region. Generating the plasma further includes providing a second voltage to a second electrode of the first pair of linear electrodes. The second voltage may be of opposite polarity to the first voltage. The second electrode extends from the first edge of the plasma generating region to the second edge of the plasma generating region. The second electrode is substantially parallel to the first electrode.

In another aspect of the present disclosure, a process chamber includes a substrate support. The substrate support is configured to maintain a surface of a substrate in a first plane. The process chamber further includes a plasma generating component. The plasma generating component includes a first pair of linear electrodes. Each electrode of the first pair of linear electrodes extends from a first edge of a plasma generating region of the plasma generating component to a second edge of the plasma generating region of the plasma generating component. Electrodes of the first pair of linear electrodes are substantially parallel. The plasma generating component further includes a second pair of linear electrodes. The second pair of linear electrodes is substantially parallel to the first pair of linear electrodes. The first pair of linear electrodes and the second pair of linear electrodes lie in a second plane, substantially parallel to the first plane. The plasma generating component further includes a dielectric support to which the first pair of linear electrodes and the second pair of linear electrodes are secured.

### BRIEF DESCRIPTION OF THE DRAWINGS

The present disclosure is illustrated by way of example, and not by way of limitation in the figures of the accompanying drawings.

FIG. 1A is an illustrative diagram of a plasma generation component including an array of linear plasma sources, according to some embodiments.

FIG. 1B is an illustrative diagram of a side view of a plasma processing system, according to certain embodiments.

FIG. 1C is a diagram illustrating electrical connections between electrodes of a plasma generation component and a power supply, according to some embodiments.

FIG. 1D depicts a bottom view of a plasma generation component, according to some embodiments.

FIG. 2A depicts an example of a substrate with a central zone of plasma generation, a substrate with an edge zone of plasma generation, and a substrate with an intermediate zone of plasma generation, according to some embodiments.

FIG. 2B is a diagram depicting example exposure of a substrate to plasma generated by plasma sources organized into zones, according to some embodiments.

FIG. 3 is a block diagram illustrating an example system architecture for plasma processing of substrates, according to some embodiments.

FIG. 4 depicts a block diagram of an example data set generator to create data sets for training, testing, validating, etc., a model, according to some embodiments.

FIG. 5 is a block diagram illustrating a system for generating output data, according to some embodiments.

FIG. 6A is a flow diagram of a method for generating a data set for a machine learning model, according to some embodiments.

FIG. 6B is a flow diagram for a method for generating plasmas for substrate processing, according to some embodiments.

FIG. 6C is a flow diagram of a method for training a machine learning model for configuring plasma generation, according to some embodiments.

FIG. 6D is a flow diagram of a method for utilizing a trained machine learning model for configuring plasma generation, according to some embodiments.

FIG. 7 depicts a block diagram of an example computing device capable of operations associated with plasma delivery and/or plasma processing, according to some embodiments.

### DETAILED DESCRIPTION

A common target for a plasma processing is a high uniformity of a process result (e.g., a uniformity across a substrate up to the very edge of the substrate). This uniformity target is often very difficult to achieve. Plasma process uniformity involves many factors, many of which interfere with others. Plasma uniformity, chamber design, wafer temperature distribution, design of the bias electrode, etc. are only part of these factors. Typical process uniformity requirement in today's semiconductor manufacturing is around 1%-2% across the whole wafer, with exclusion of 1-3 mm from the edge. Different uniformity controlling methods may be effective for some processes and completely useless for others. These stringent constraints that continuously get even firmer call for new methods for controlling process uniformity instead of or in addition to existing methods.

Some methods of plasma generation include generating plasma gas in a fairly large volume proximate a surface of a substrate. In some methods plasma may be generated by applying current to a coil around a target plasma generation volume. In some methods, plasma may be produced by generating a voltage difference between two electrodes, where the target plasma generation volume and the substrate are between the two electrodes.

Such solutions as provided above may suffer in terms of plasma uniformity across the surface of the substrate, across the target plasma generation volume, or the like. A large plasma generation volume may be susceptible to non-uniformities due to proximate components. For example, significant edge effects may be introduced by chamber walls. One solution to edge effects may be to increase the size of a process chamber, but this leads to other inefficiencies of materials, weight, and size of process chambers.

Some solutions introduce highly controlled plasma generation systems. Many different control options may be available in numerous combinations. Solutions to process non-uniformity that rely on increased control may suffer from inconvenience or excessively burdensome recipe and run inputs, a large amount of baseline data (e.g., many process runs) to calibrate or optimize multidimensional controls, etc.

Aspects of the present disclosure may address one or more shortcomings of existing plasma processing devices. In some embodiments, a one-dimensional array of linear plasma sources is described. Each plasma source of a plasma generating component may include a pair of linear electrodes. “Linear,” in this case, means approximately straight, and significantly larger in one dimension than a second and third dimensions (e.g., an electrode at least 10 times as long as it is wide). For example, linear electrodes may have an aspect ratio of anywhere from 5:1 to 200:1 (e.g., 5:1, 6:1, 7:1, 8:1, 9:1, 10:1, 11:1, 21:1, 13:1, 14:1, 15:1, 16:1, 17:1, 18:1, 19:1, 20:1, 21:1, 22:1, 23:1, 24:1, 25:1, 26:1, 27:1, 28:1, 29:1, 30:1, 50:1, 100:1, 200:1, intermediate aspect ratios, etc.). The electrodes of a plasma source may be approximately parallel. The electrodes may be disposed on a plasma generating component. The plasma generating component may include a number of sources, each including a parallel pair of linear electrodes. Each of the sources may approximately generate a line of plasma, or rather a region of plasma generation much longer than it is wide. The generated plasma may have an aspect ratio of length to width that approximately corresponds to an aspect ratio of the linear electrodes in embodiments. Each of the sources may be approximately parallel. The plasma generating component may be disposed proximate (e.g., above) a surface of the substrate to be processed. The plasma generating component may be suspended above a substrate supported by a substrate support system, such as an electrostatic chuck.

A plasma source (e.g., pair of electrodes) of the plasma generating component may generate an essentially uniform line of plasma. An array of sources (e.g., a one-dimensional array in the perpendicular direction to the length of the linear electrodes) may generate an essentially uniform exposure of a substrate to plasma. In some embodiments, a distance between the substrate and the plasma generating component may be quite small. In some embodiments, a distance between the substrate and the plasma generating component may be chosen to generate some overlap of plasma exposure at the substrate from adjacent plasma sources. In some embodiments, a distance between the substrate and the plasma generating component may be related to a distance between plasma sources of the plasma generating component. In some embodiments, the linear plasma sources are approximately horizontal, such that one end of the linear plasma sources has approximately a same distance to a substrate as an opposite end of the linear plasma sources. A distance between a plasma source and the substrate may be small enough to provide a local effect on the substrate in the direction perpendicular to the length of the linear plasma sources.

A plasma generating component may be configured to provide one-dimensional control, e.g., along the axis perpendicular to the length of the electrodes of the plasma generating component. Plasma sources of a plasma generating component may be individually controllable. Plasma sources of a plasma generating component may be controllable in two or more zones.

In some embodiments, a plasma generation component may include a number of linear plasma sources that cover the whole area above the substrate and powered by the same power supply. The controllable version of this array allows turning ON and OFF individual sources or zones, where each zone may contain several sources and the number of sources may differ from zone to zone. Controlling the time the individual zone or the source generates plasma (ON), one controls the process uniformity on the substrate.

In some embodiments, an array of linear plasma sources may utilize dielectric barrier discharge plasma generation techniques. A plasma generation component may be applicable to a range of process conditions. An array of linear plasma sources may be utilized at pressures below 1 Torr to above 100 Torr. In some embodiments, a facility may have multiple complementary substitutable plasma generation components. In some embodiments, different plasma generation components may perform differently (e.g., more favorably, produce plasma with different properties, etc.) in different process condition. In some embodiments, a machine learning model may be utilized to select a plasma generation component suited for a target process operation, process procedure, or the like.

In some embodiments, further improvements to process uniformity may be made. An introduction of a rotating stage (e.g., rotating substrate support) may improve process uniformity. Such a rotating state may rotate about an axis that is normal to a surface of a substrate. Non-uniformity of any process on a substrate may be divided into two components, radial and azimuthal. Radial components affect substrate processing (e.g., exposure of the substrate to plasma) as a function of radius from some central location. Azimuthal components are related to angle-dependent process non-uniformities. Rotation of a substrate may reduce or eliminate azimuthal non-uniformity. Rotation of a substrate may not be controlled, e.g., the stage may rotate without providing any feedback or instruction to control plasma generation. Alternatively, rotation of the stage (and thus of the substrate) may be controlled. For example, a rotation speed of the stage may be determined based on one or more criteria. In embodiments, rotation speed may be selected before processing and/or may be changed dynamically during processing.

Aspects and implementation of the present disclosure may address these and other potential shortcomings of conventional systems. Large plasma volumes may be difficult to carefully control. Elements of plasma generation, elements of chamber construction, etc., have an effect upon plasma uniformity which may be difficult or impossible to untangle to achieve acceptably uniform plasma generation. Spatial scales of influences on plasma generation may differ. Sidewalls may affect recombination of gas species, gas temperature variations, gas flow patterns, etc. Sidewall contributions may be reduced by reducing an active plasma volume, e.g., by providing a linear plasma generation component close to the surface of the substrate.

A one-dimensional array of linear sources extending through a target plasma generation volume (e.g., from one edge of the volume to the opposite edge) may improve plasma uniformity without cumbersome control schemes. In some embodiments, plasma may be sufficiently uniform (e.g., generate a level of exposure uniformity that satisfies one or more threshold conditions) without any separate control of plasma sources. In some embodiments, simple zone control may be sufficient to achieve adequate process uniformity. In some embodiments, control in one dimension may be sufficient to achieve adequate process uniformity.

In some cases, process non-uniformity may not be achievable via one-dimensional control. For example, in some cases it can be difficult in particular to control radial process non-uniformities. Rotation of a substrate (e.g., constant uncontrolled rotation) under an array of approximately uniform plasma sources converts two-dimensional non-uniformity to a one-dimensional non-uniformity problem. Rotation of the substrate may convert radial and azimuthal non-uniformity to non-uniformity that may be solved via one-dimensional control. One-dimensional control of a plasma generation component may be used with rotation of the substrate to correct for both azimuthal non-uniformities and radial non-uniformities of exposure of the substrate to plasma processing.

Systems and method of the present disclosure result in technological advancements over conventional systems. The current disclosure enables an increase in process uniformity of a plasma processing operations. The current disclosure enables an increase in exposure uniformity of a substrate to process plasma. The current disclosure enables use of a simple control scheme (e.g., time-based control, zone control, control of plasma generation independent of substrate rotation, etc.) for process uniformity.

In one aspect of the present disclosure, a plasma generating component for a process chamber includes a first pair of linear electrodes. Each electrode of the first pair of linear electrodes extends from a first edge of a plasma generating region of the plasma generating component to a second edge of the plasma generating region of the plasma generating component. Electrodes of the first pair of linear electrodes are substantially parallel. The plasma generating component further includes a second pair of linear electrodes, substantially parallel to the first pair of linear electrodes. The plasma generating component further includes a dielectric support to which the first pair of linear electrodes and the second pair of linear electrodes are secured. The plasma generating component further may include a dielectric layer covering electrodes opposite the dielectric support.

In another aspect of the present disclosure, a method includes generating a plasma for substrate processing. Generating the plasma includes providing a first voltage to a first electrode of a first pair of linear electrodes. The first electrode extends from a first edge of a plasma generating region to a second edge of the plasma generating region. Generating the plasma further includes providing a second voltage to a second electrode of the first pair of linear electrodes. The second voltage is of opposite polarity to the first voltage. The second electrode extends from the first edge of the plasma generating region to the second edge of the plasma generating region. The second electrode is substantially parallel to the first electrode.

In another aspect of the present disclosure, a method includes generating a plasma for substrate processing. Generating the plasma includes providing a first voltage between electrodes of a first pair of linear electrodes. Generating the plasma further includes alternating the voltage between electrodes of the first pair of linear electrodes. The alternating voltages between electrodes are of opposite polarity to the previous voltage in the sequence. Alternating voltages between any of electrodes and the ground may be of the same or opposite polarities. The electrodes of the first pair extend from a first edge of a plasma generating region to a second edge of the plasma generating region. The second electrode of the first pair is substantially parallel to the first electrode.

In another aspect of the present disclosure, a process chamber includes a substrate support. The substrate support is configured to maintain a surface of a substrate in a first plane. The process chamber further includes a plasma generating component. The plasma generating component includes a first pair of linear electrodes. Each electrode of the first pair of linear electrodes extends from a first edge of a plasma generating region of the plasma generating component to a second edge of the plasma generating region of the plasma generating component. Electrodes of the first pair of linear electrodes are substantially parallel. The plasma generating component further includes a second pair of linear electrodes. The second pair of linear electrodes is substantially parallel to the first pair of linear electrodes. The first pair of linear electrodes and the second pair of linear electrodes lie in a second plane, substantially parallel to the first plane. The plasma generating component further includes a dielectric support to which the first pair of linear electrodes and the second pair of linear electrodes are secured.

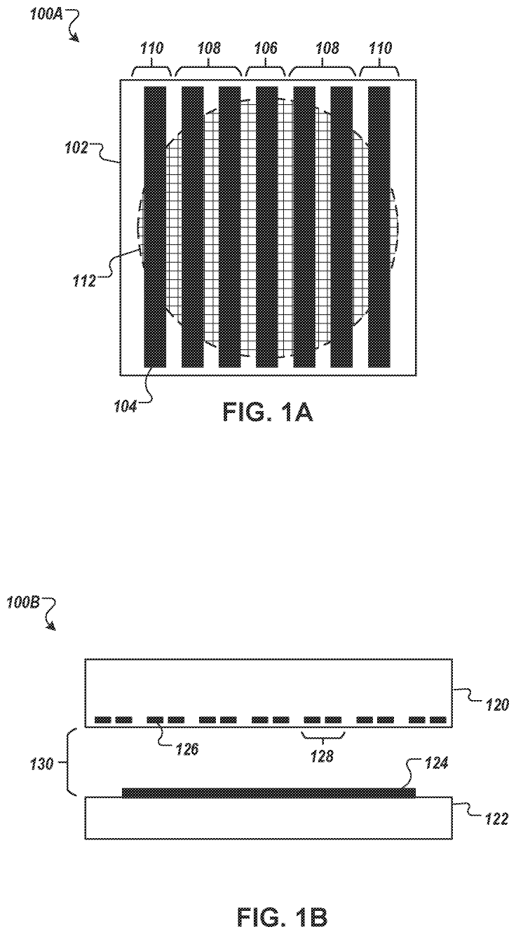

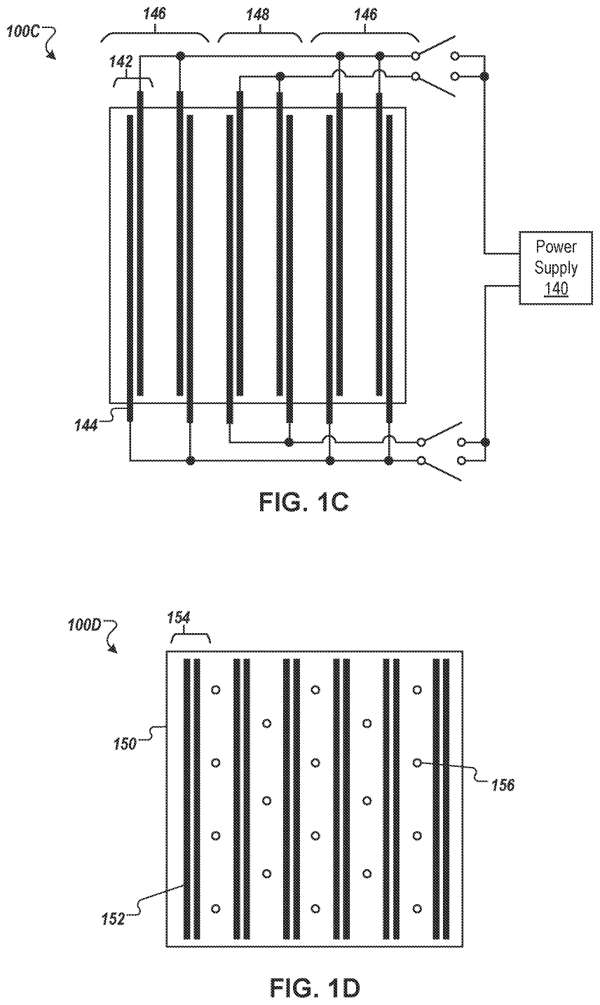

FIG. 1A is an illustrative diagram of a plasma generation component 100A including an array of linear plasma sources, according to some embodiments. Plasma generation component 100A includes body 102. Body 102 may be of a dielectric material. Body 102 may be a dielectric plate. Plasma generation component 100A includes linear plasma sources 104. Each plasma source 104 may include two linear electrodes, as depicted in FIGS. 1B-C. Each plasma source 104 may generate a line of plasma (e.g., a cloud of plasma that is long compared to its width) proximate plasma generation component 100A. Plasma of one of the linear plasma sources 104 may overlap with plasma from adjacent sources at the substrate. Overlapping plasma may improve process uniformity, exposure uniformity, etc. Each plasma source 104 may extend approximately from one end of a target plasma generation zone 112 to an opposite end of target plasma generation zone 112. Some plasma sources may extend beyond an edge of target plasma generation zone 112. The plasma generation component 100A may include an array of substantially parallel linear plasma sources.

Plasma sources 104 may include metal electrodes. Electrodes of plasma sources 104 may be deposited on body 102. Electrodes of plasma sources 104 may be deposited on a dielectric plate. Additional dielectric material may be disposed on top of plasma sources 104. In some embodiments, plasma generation component 100A may include a thick dielectric layer, electrodes, and a thin dielectric layer, as depicted in FIG. 1B.

In some embodiments, plasma along the length of a plasma source 104 may be approximately uniform. Plasma compared between plasma sources 104 may be less uniform than plasma along a single plasma source. Plasma generated by a single plasma source may be approximately uniform along the entirety of the plasma generation region associated with the plasma source, while plasma generated by different sources may vary more dramatically. Plasma generation component 100A may be configured to provide separate control of one or more plasma sources 104. In some embodiments, the array of plasma sources 104 (e.g., identical pairs of electrodes) can be individually set to an ON or OFF state. Setting a plasma source 104 to an ON or OFF state may be accomplished via hardware solutions (e.g., a switch separating a plasma source 104 from a power supply). Setting a plasma source 104 to an ON or OFF state may be accomplished via a logic solution (e.g., via a processing device, microcontroller, logic circuit, etc.). Setting a plasma source 104 to an ON or OFF state may be performed digitally, e.g., via addressing. An ON state is associated with activation of plasma generation and an OFF state may be associated with deactivation of plasma generation. In some embodiments, the entire array of plasma sources 104 may be controlled together, e.g., may be set to ON or OFF as a unit. In some embodiments, the array of plasma sources 104 may be separated into zones, and zones may be set to ON or OFF states together. Zones may include the same or different numbers of plasma sources 104.

Plasma sources 104 may use dielectric barrier discharge (DBD) technology. An advantage of dielectric barrier discharge is that a common voltage waveform from a single power supply can be applied (e.g., configured to supply) to all plasma sources 104, but discharges will occur only in selected sources. An alternating voltage (±Vₛ) at frequency f from a power supply (e.g., AC generator) can generate a series of identical discharge pulses of the 2f frequency in selected sources. A discharge pulse can occur after every change of polarity. The total amount of plasma related particles (ions, electrons, radicals) generated by any source is proportional to the number of pulses supplied to that source, generated in that source, etc. The voltage may alternate at a radio frequency (RF).

A combination of different durations can be used to generate exposure patterns with activation and deactivation of plasma sources 104. In some embodiments, exposure patterns include data having a set of exposure durations mapped to individual plasma sources, zones of plasma sources, or the entire plasma generation component 100A. The plasma sources 104 may be controlled in one dimension, e.g., the dimension perpendicular to the length (e.g., long direction) of the plasma sources. In some embodiments, an exposure pattern may include duration values in different formats (e.g., quantities of time, number of plasma pulses, etc.) that can be mapped to the plasma sources 104 such that each plasma source 104 permits passage or generate plasma related fluxes for an associated exposure duration.

Plasma sources 104 of plasma generation component 100A may be organized into zones. Zones may be organized based on corresponding location on a substrate processed using plasma generation component 100A. With substrate rotation (e.g., rotation uncoupled to plasma processing, constant rotation, etc.), control along a single axis translates to radial control. Control along an axis perpendicular to the length of plasma sources 104 may translate to radial control of substrate exposure. With substrate rotation, azimuthal non-uniformities may be reduced or eliminated. Zones may be organized based on translated exposure zones, e.g., radial zones. Plasma generation component 100A may include a central zone 106, including plasma sources passing through a central region of a target plasma generation volume. Plasma sources of a central zone may intersect a central area of the plasma generation volume. Plasma sources of a central zone may overlap with a central portion of a plasma generating region of the plasma generating component.

Plasma generation component 100A may include an edge zone 110. Edge zone 110 may include plasma sources that are along an edge of target plasma generation component 100A. Plasma sources of an edge zone may intersect an edge area of the plasma generation volume. Plasma generation component 100A may include an intermediate zone 108, including plasma sources 104 between central zone 106 and edge zone 110. A plasma generation component may include more plasma source zones than depicted in FIG. 1A. A plasma generation component may include fewer plasma source zones than depicted in FIG. 1A. Each zone of plasma sources of a plasma generation component may include any target number of plasma sources.

Plasma generation component 100A may be of a different shape than shown in FIG. 1A, e.g., circular, rectangular, elliptical, octagonal, etc. Plasma generation components (including an array of linear plasma sources) of different shape are within the scope of this disclosure. In some embodiments, plasma sources 104 of plasma generation component may not be of the same length, e.g., plasma sources passing through the center of the plasma generation region may be longer than plasma sources that only pass through an edge of the plasma generation region.

FIG. 1B is an illustrative diagram of a side view of a plasma processing system 100B, according to some embodiments. Plasma processing system 100B includes plasma generation component 120 (e.g., plasma generation component 100A of FIG. 1A), substrate support 122, and substrate 124. Substrate 124 may be a semiconductor substrate. Substrate 124 may be a semiconductor wafer. Substrate 124 may be (or be a precursor to) a memory device, logic device, etc.

Plasma generation component 120 may include a dielectric plate. Plasma generation component 120 may include a series of plasma sources 128. Each plasma source 128 may include a pair of electrodes 126. Each electrode of a pair of electrodes may be provided a voltage relative to the voltage provided to the other electrode of the pair of electrodes. Between electrodes of each pair of electrodes there may be a voltage provided. For example, in some embodiments, one electrode may be connected to ground, while another is provided with an oscillating voltage. In some embodiments, oscillating voltage may be applied between each electrode and the ground with a phase shift between voltages applied to the two electrodes of a pair of electrodes. In some embodiments, the phase shift may be 180°. In some embodiments, electrodes of a pair of electrodes may be provided with oscillating voltages of opposite polarity. Voltage between electrodes of each pair of electrodes may cause dielectric breakdown, plasma generation, etc. Plasma may be generated primarily in a target plasma generation region 130.

Plasma generation component 120 may include electrodes 126 disposed on a dielectric medium. In some embodiments, the electrodes 126 may be deposited upon the dielectric medium, e.g., via additive manufacturing. In some embodiments, electrodes 126 may be surrounded by one or more dielectric components, media, etc. Electrodes 126 may be disposed between a thick dielectric layer and a thin dielectric layer. Electrodes 126 may be deposited on a thick dielectric layer, and a further thin dielectric layer may be deposited on the electrodes 126.

Proximity of plasma generation component 120 to substrate 124 may affect process conditions of substrate 124. In some embodiments, a distance between substrate support 122 and plasma generation component 120 may be tuned to improve exposure uniformity (e.g., of substrate 124 to plasma). A distance between substrate support 122 and plasma generation component 120 may be chosen to allow overlap of plasma generated by adjacent plasma sources 128. A distance between substrate support 122 and plasma generation component 120 may be related to a distance between plasma sources 128, a distance between plasma electrodes 126, etc. For example, a target distance between plasma generation component 120 and substrate support 122 larger than a distance between centers of adjacent plasma sources 128 may improve exposure uniformity of substrate 124 to process plasma.

FIG. 1C is a diagram illustrating electrical connections between electrodes of a plasma generation component 100C and a power supply 140, according to some embodiments. FIG. 1C depicts a simple system, eliminating many potential electrical components, for clarity.

Each plasma source 142 of plasma generation component 100C includes a pair of electrodes 144. In some embodiments, two electrodes of a source may be provided a voltage of opposite polarity. For example, power supply 140 may provide an alternating current voltage (e.g., at frequencies in the Hz-MHz range). Power supply 140 may provide voltage to the two electrodes 144 of a plasma source 142 that are 180 out of phase. Power supply 140 may include multiple terminals. Various electrodes may be connected to a single terminal. Some electrodes may be electrically coupled to a first terminal of power supply 140, some to a second terminal of power supply 140, etc.

In some embodiments, power may be supplied to the two electrodes 144 of a plasma source 142 from opposite sides of plasma generation component 100C. Plasma may be generated between electrodes 144 that are connected to power via opposite edges of plasma generation component 100C. Providing power to electrodes of a plasma source from opposite ends may improve plasma generation. Non-ideal nature of electrodes and structure (e.g., resistance, capacitance, inductance, etc.) may cause some unexpected behavior while providing power to the electrodes. Providing power to pairs of electrodes from opposite sides may improve plasma uniformity in view of the non-ideal nature of the electrodes. Powering pairs of electrodes from opposite sides may reduce a potential time delay or intensity delay that may be present between a connected end and a far end of electrodes configured to be powered from the same side of a plasma generation component.

Electrodes of plasma generation component 100C are organized into two zones. Plasma sources of plasma generation component 100C are organized into an edge zone 146 and a center zone 148. Plasma sources of center zone 148 pass through a central region of a target plasma generation region. Providing power to each zone of plasma sources may be controlled, e.g., by switching power ON or OFF for electrodes of the zone. In some embodiments, individual plasma sources may be controlled. In some embodiments, global control is provided (e.g., no separate control of plasma sources). Exposure of a substrate associated with a zone of plasma sources may be controlled by controlling a duration of time that plasma sources of that zone are active.

Electrodes 144 of plasma generation component 100C are connected to power in such a way that adjacent electrodes 144 that belong to different plasma sources 142 are connected to power of the same polarity, e.g., following an ABBA connection pattern. An ABBA connection pattern may reduce unintentional or unwanted interactions between adjacent electrodes 144 of different plasma sources 142. Other connection patterns are possible, e.g., ABAB, and may be more convenient in some systems.

FIG. 1C depicts a hardware solution to plasma control, e.g., introduction of switches that separate power supply 140 from electrodes 144. Other solutions are possible and within the scope of this disclosure, e.g., logic control, digital control, addressing, etc.

Control of exposure (e.g., for process uniformity) may be achieved via time control of various plasma generation zones. Control of exposure may further be achieved by manipulating frequency of discharge of a plasma source, e.g., by manipulating frequency of an alternating current provided to electrodes 144. In some embodiments, one or more electrodes, one or more zones, etc., may be coupled to a frequency adjusting component (e.g., frequency multiplier, frequency divider, etc.). The frequency adjusting component may adjust plasma generation, exposure of a substrate to process plasma, etc. In some embodiments, multiple frequency adjusting components may be included in the plasma processing system for additional control, flexibility, or the like.

Control of exposure (e.g., for process uniformity) may be performed by providing different power to different electrodes, different plasma sources, different zones, etc. This may be accomplished, for example, by utilizing multiple power supplies. Providing different power may be accomplished by adjusting a voltage provided to a plasma source.

FIG. 1D depicts a bottom view of a plasma generation component 100D, according to some embodiments. In some embodiments, FIG. 1D may correspond to a top view of the plasma generation component 100D. Plasma generation component 100D includes a dielectric plate 150. Plasma generation component 100D includes a one-dimensional array of plasma sources 154, each including a pair or electrodes 152.

Plasma generation component 100D further includes gas delivery apertures 156. Gas delivery apertures 156 may be gas outlets. Gas delivery apertures 156 may be gas outlets associated with a common gas inlet and gas distribution volume associated with the plasma generation component 100D. Gas delivery apertures 156 may be disposed on the side of plasma generation component 100D closest to a substrate for processing (e.g., typically the bottom surface of plasma generation component 100D). Gas delivery apertures 156 may be used to deliver process gas, flushing gas, cleaning gas, or the like to a volume proximate the plasma generation component 100D. Gas delivery apertures 156 may be used to deliver gas to a surface of a substrate for processing. Gas delivery apertures 156 may be disposed between plasma sources 154 of plasma generation component 100D. Gas delivery apertures 156 may be disposed between electrodes 152 of a plasma source 154. In some embodiments, gas may instead be delivered via a different path, e.g., introduced to the space between plasma generation component 100D and a substrate from around the edges of plasma generation component 100D.

Gas delivery apertures 156 may be fluidly coupled to one or more gas inlets (not shown) of plasma generation component 100D. Gas inlets may be on a different surface of plasma generation component 100D, e.g., the top surface. Gas inlets may be on the surface of plasma generation component 120 depicted as the top surface in FIG. 1B. A gas inlet may be fluidly coupled to a plurality of gas delivery apertures 156.

In some embodiments, gas delivery apertures 156 may be separated into zones. Gas delivery apertures 156 may be separated into gas delivery zones. Different zones may be fluidly coupled to different sets of gas inlets. For example, gas delivery apertures 156 may be separated into a central zone (e.g., proximate the center of a substrate), an edge zone, an intermediate zone, etc. In some embodiments, gas may be delivered independently to different zones. Independent gas delivery may enable different gas mixes or pressures to be delivered to different areas of a substrate, different regions of a target plasma generation region, or the like.

Gas delivery apertures 156 may provide gas for plasma processing. A plasma generation component including a one-dimensional array of parallel linear electrodes may be operated at a range of gas pressures. A plasma generation component including a one-dimensional array of parallel linear electrodes may be operated at low pressures. A plasma generation component may be operated at fairly high pressures. Plasma generation procedures may be performed in a range of pressure conditions. A plasma generation component may be operated at gas pressures below one torr, to above 100 torr. A plasma generation component may be operated between 0.1 and 200 torr. A plasma generation component may be operated between 1 torr and 100 torr. A plasma generation component may be operated between 1 and 20 torr, between 10 and 80 torr, between 20 and 200 torr, or any other combination or sub-interval of gas pressures.

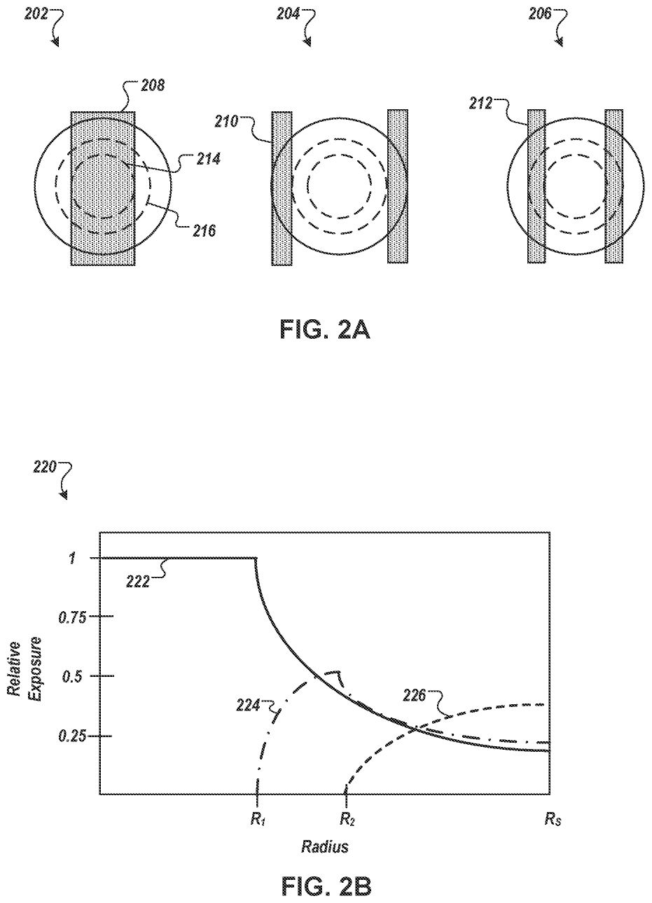

FIG. 2A depicts an example of a substrate with a central zone of plasma generation 202, a substrate with an edge zone of plasma generation 204, and a substrate with an intermediate zone of plasma generation 206, according to some embodiments. Upon substrate rotation, zone-based plasma generation control in one dimension of an array of linear plasma sources translates to radial exposure control on a substrate. A substrate interaction with plasma may be adjusted by causing rotation of the substrate relative to the plasma generation apparatus. Details of zones may be different than displayed in FIG. 2A, e.g., more zones, fewer zones, etc. In some embodiments, plasma sources may be configured for individual control, and may be organized into zones by control software, control hardware, recipe instructions, etc. Zones may differ between different plasma generation components, different recipes, etc.

A plasma generation region may be separated into a number of zones. A plasma generation region may include a central zone 208. A plasma generation region may include an edge zone 210. A plasma generation region may include an intermediate zone 212. Zones may be electrically coupled to power (e.g., one or more power supplies, voltage supplies, or the like) as a group. Zones may be electrically decoupled from other zones. In some embodiments, one or more switches may enable adjusting which zones are provided with power. In some embodiments, different power supplies or different terminals may provide power to different zones. In some embodiments, zones may perform differently (e.g., provide different levels of exposure of a substrate to plasma) by adjusting a time or duration that a zone provides plasma, or adjusting a power provided to plasma sources of the zone. In some embodiments, adjusting power provided to a plasma source or zone of plasma sources may include adjusting a frequency f of applied voltages, adjusting the value of applied voltages (e.g., the voltage gap between electrodes of a source), etc. Adjusting power provided to a plasma source may include adjusting an RF frequency of applied voltage.

Upon substrate rotation, control of an array of plasma generation in one dimension may translate to radial control of substrate exposure to plasma. Boundaries between plasma zones may translate to boundaries between radial exposure regions. Boundaries between plasma generation zones of FIG. 2A translate to radial boundaries on substrate of radial boundary R₁ 214 and radial boundary R₂ 216. Central zone 208 targets regions of a substrate closer to the center of the substrate than the radius associated with radial boundary R₁ 214. Edge zone 210 targets regions of a substrate farther from the center of the substrate than the radius associated with radial boundary R₂ 216. Intermediate zone 212 targets regions of a substrate that are between a first distance associated with radial boundary R₁ 214 and a second distance associated with a second radial boundary R₂ 216 from the center of the substrate.

FIG. 2B is a diagram 220 depicting example exposure of a substrate to plasma generated by plasma sources organized into zones, according to some embodiments. Radius is indexed along the x-axis of diagram 220. The radius of the substrate is separated into three zones, defined by a first radius R₁, a second radius R₂, and the full radius of the substrate R_{S}. R₁, R₂, and R_{S} may correspond to radial boundary R₁ 214, radial boundary R₂ 216, and the substrate radius shown in FIG. 2A. The y-axis of diagram 220 presents relative exposure as a function of radius. Exposure is normalized to a maximum exposure of 1 to generate relative exposure.

Diagram 220 includes central zone exposure 222. A central zone of plasma generation may provide maximum exposure to portions of the substrate proximate the center of rotation of the substrate. Portions of the substrate further from the center (e.g., beyond R₁) also receive some plasma exposure as the substrate is rotated, bringing these portions of the substrate under the linear plasma sources of the central zone.

Diagram 220 includes intermediate zone exposure 224. An intermediate zone of plasma generation may not provide significant plasma exposure to regions of a substrate close to the axis of rotation of the substrate, e.g., at radii less than R₁. An intermediate zone of plasma generation may provide peak exposure at a particular radius R₂.

Diagram 220 includes edge zone exposure 226. An edge zone of plasma generation may not provide significant plasma exposure to regions of a substrate close to the axis of rotation of the substrate, e.g., at radii less than R₂. An edge zone may provide maximum exposure along an outer edge of the substrate, an outer edge of the edge zone, etc.

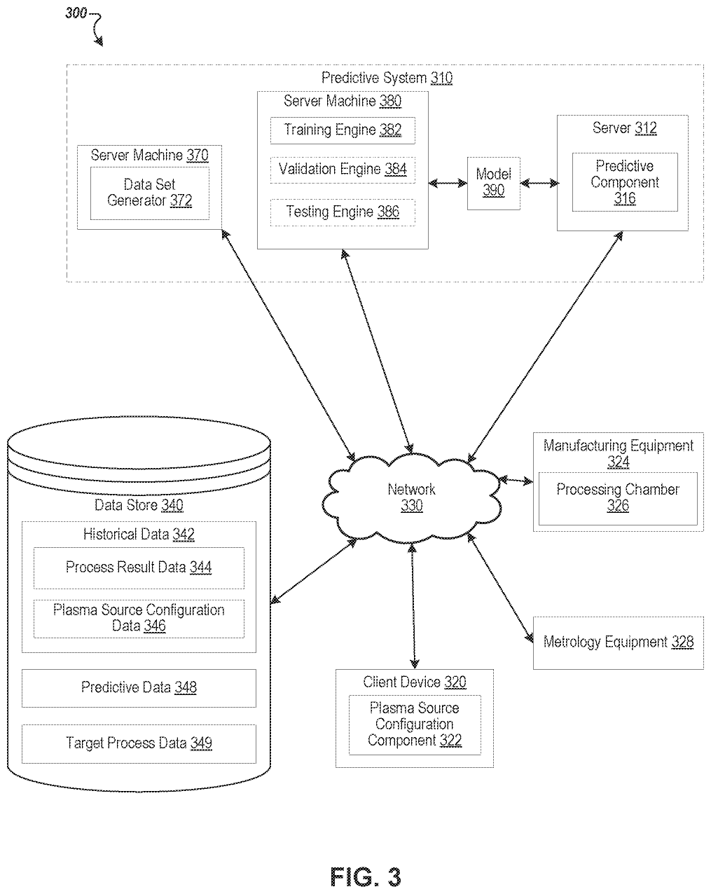

FIG. 3 is a block diagram illustrating an exemplary system architecture 300 in which implementations of the disclosure may operate. System architecture 300 includes a client device 320, manufacturing equipment 324, metrology equipment 328, a server 312, and a data store 340. The server 312 may be part of a predictive system 310. The predictive system 310 may further include server machines 370 and 380.

Manufacturing equipment 324 (e.g., associated with producing, by manufacturing equipment 324, corresponding products, such as wafers) may include one or more processing chambers 326.

The client device 320, manufacturing equipment 324, metrology equipment 328, server 312, data store 340, server machine 370, and server machine 380 may be coupled to each other via a network 330 for modeling process results and plasma source configurations (e.g., for improving process uniformity of substrate processing within processing chambers 326).

In some embodiments, network 330 is a public network that provides client device 20 with access to the server 312, data store 340, and/or other commonly available computing devices. In some embodiments, network 330 is a private network that provides client device 320 access to manufacturing equipment 324, metrology equipment 328, data store 340, and/or other privately available computing devices. Network 330 may include one or more Wide Area Networks (WANs), Local Area Networks (LANs), wired networks (e.g., Ethernet network), wireless networks (e.g., an 802.11 network or a Wi-Fi network), cellular networks (e.g., a Long Term Evolution (LTE) network), routers, hubs, switches, server computers, cloud computing networks, and/or a combination thereof.

The client device 320 may include a computing device such as Personal Computers (PCs), laptops, mobile phones, smart phones, tablet computers, netbook computers, network connected televisions (“smart TV”), network-connected media players (e.g., Blu-ray player), a set-top-box, Over-the-Top (OTT) streaming devices, operator boxes, etc. The client device 320 may include a plasma source configuration component 322. Plasma source configuration component 322 may receive data from metrology equipment 328 such as process result data and displays the process result data on the client device 320. The plasma source configuration component 322 may interact with one or more elements of predictive system 310 to determine one or more plasma source configurations. Plasma source configuration component 322 may determine plasma source configurations to be disposed within processing chamber 326 to process a substrate that meets threshold criteria (e.g., process uniformity requirements).

Data store 340 may be a memory (e.g., random access memory), a drive (e.g., a hard drive, a flash drive), a database system, or another type of component or device capable of storing data. Data store 340 may store one or more historical data 342 including process result data 344 and/or plasma source configuration data 346. In some embodiments, the historical data 342 may be used to train, validate, and/or test a machine learning model 390 of predictive system 310. Plasma source configuration data may include data associated with multiple control schemes of a plasma generation component, data associated with performance of multiple different plasma generation components, etc.

Data store 340 may further include target process data 349. Target process data 349 may include target substrate profiles, target exposure profiles, etc. Target process data 349 may include target results of a process procedure, e.g., target substrate design. Data store 340 may further include predictive data 348. Predictive data 348 may be data output by predictive component 316, model 390, predictive system 310, etc. Predictive data 348 may include predicted plasma source configurations (e.g., for achieving a target process result). Predictive data 348 may include recommended plasma generation system configurations, such as recommending a plasma generation component from a group of available components, recommending a grouping/zoning of plasma sources, etc. Predictive data 348 may include control data, e.g., data describing timing for switching one or more electrodes, sources, zones, etc., to an ON state and/or an OFF state to achieve a target process result.

Predictive system 310 may include one or more computing devices such as a rackmount server, a router computer, a server computer, a personal computer, a mainframe computer, a laptop computer, a tablet computer, a desktop computer, etc. In some embodiments, predictive system 310 may include a predictive component 316. Predictive component 316 may take data retrieved from metrology equipment 328 to generate plasma source configuration data 346. The predictive component receives metrology data from metrology equipment 328. The metrology data may include a process result profile associated with a substrate processed in processing chamber 326. The predictive component determines (e.g., using model 390) a plasma source configuration. The plasma source configuration may include an arrangement of plasma sources (e.g., plasma sources 104 of FIG. 1A) and/or an exposure pattern (e.g., activation duration/cadence of individual plasma generation cells). In some embodiments, the plasma source configuration includes electrical connection arrangements to the plasma generating elements such as one or more of the plasma generation sources are arranged in zones, each source is controlled independently one from another, and/or the like. The plasma source configuration may further include specifications of individual plasma generating elements (e.g., brightness, power, voltage, current, plasma generation capabilities, etc.) For example, a substrate processed in a processing chamber using the plasma source configuration results in a processed substrate having process results meeting threshold criteria (e.g., process uniformity requirements).

In some embodiments, the predictive component 316 may use historical data 342 to determine a plasma generation configuration that when applied to a processing chamber results in a substrate processed in the chamber that meet threshold criteria (e.g., process uniformity requirements). In some embodiments, the predictive component 316 may use a model 390 (e.g., trained machine learning model) to identify plasma source configurations when utilized by a processing chamber result in a substrate with process results meeting a threshold condition (e.g., process uniformity requirements). The model 390 may use historical data to determine the plasma source configurations. The model 390 may use target process data 349 to determine plasma source configurations.

In some embodiments, the predictive system 310 further includes server machine 370 and server machine 380. The server machine 370 and 380 may be one or more computing devices (such as a rackmount server, a router computer, a server computer, a personal computer, a mainframe computer, a laptop computer, a tablet computer, a desktop computer, etc.), data stores (e.g., hard disks, memories databases), networks, software components, cloud computing or cloud memory systems, or hardware components.

Server machine 370 may include a data set generator 372 that is capable of generating data sets (e.g., a set of data inputs and a set of target outputs) to train, validate, or test a machine learning model.

Server machine 380 includes a training engine 382, a validation engine 384, and a testing engine 386. Server machine 380 may further include a selection engine (not shown). The training engine 382 may be capable of training a model 390 (e.g., machine learning model) using one or more process result data 344 and plasma source configuration data 346. The validation engine 384 may determine an accuracy of each of models 390 based on a corresponding set of features of each training set. The validation engine 384 may discard models 390 that have an accuracy that does not meet a threshold accuracy. The testing engine 386 may determine a model 390 that has the highest accuracy of all of the trained machine learning models based on the testing (and, optionally, validation) sets. In some embodiments, a selection engine may determine a model 390 that has the highest accuracy.

In some embodiments, the training data is provided to train the model 390 such that the trained machine learning model is to receive a new input and produce a predictive output. Model 390 may be configured to receive a target process result (e.g., target process data 349) and generate a recipe for plasma generation, e.g., timings for switching various plasma generation zones to ON and/or OFF states. Model 390 may be configured to receive a target process result and generate a recommended zone arrangement for a plasma generation component. Model 390 may be configured to receive a target process result and generate a recommendation of a plasma generation component to be used for achieving the target process result.

In some embodiments, the plasma source configuration includes electrical connection arrangements to the plasma generating elements, such as one or more of the plasma generation elements are arranged in zones, chained together to form an array, each electrode or source is controlled independently one from another, and/or the like. The plasma source configuration may further include specifications of individual plasma generating elements (e.g., brightness, power, voltage, current, frequency, plasma generation capabilities, etc.) For example, a substrate processed in a processing chamber using the plasma source configuration results in a processed substrate having process results meeting threshold criteria (e.g., process uniformity requirements).

The model 390 may refer to the model that is created by the training engine 382 using a training set that includes data inputs and corresponding target output (historical results of cell cultures under parameters associated with the target inputs). Patterns in the data sets can be found that map the data input to the target output (e.g., identifying connections between plasma source configuration and process results), and the machine learning model 390 is provided mappings that captures these patterns. The machine learning model 390 may use one or more of logistic regression, syntax analysis, decision tree, or support vector machine (SVM). The machine learning may be composed of a single level of linear of non-linear operations (e.g., SVM) and/or may be a neural network.

Model 390 may further output confidence data. The confidence data may include or indicate a level of confidence of one or more plasma source configurations that when a substrate process a substrate according to the plasma source configuration will result in a substrate having process results that meets threshold criteria (e.g., process uniformity requirements). In one non-limiting example, the level of confidence is a real number between 0 and 1 inclusive, where 0 indicates no confidence of the one or more prescriptive actions and 1 represents absolute confidence in the prescriptive action.

For purpose of illustration, rather than limitation, aspects of the disclosure describe the training of a machine learning model and use of a trained learning model using information pertaining to historical data 342. In other implementation, a heuristic model or rule-based model is used to determine a prescriptive action. In some embodiments, model 390 including physics-based element or derive prediction through physics-based principles. For example, model 390 may include a physics-based model based on plasma and flow equations, principles, and/or simulations.

In some embodiments, the functions of client devices 320, server 312, data store 340, and modeling system 310 may be provided by a fewer number of machines than shown in FIG. 3. For example, in some embodiments, server machines 370 and 380 may be integrated into a single machine, while in some other embodiments, server machine 370 and 80 and server 9132 may be integrated into a single machine.

In general, functions described in one embodiment as being performed by client device 320, data store 40, metrology system 328, manufacturing equipment 324, and modeling system 310 can also be performed on server 312 in other embodiments, if appropriate. In addition, the functionality attributed to a particular component can be performed by different or multiple components operating together.

In embodiments, a “user” may be represented as a single individual. However, other embodiments of the disclosure encompass a “user” being an entity controlled by multiple users and/or an automated source. For example, a set of individual users federated as a group of administrators may be considered a “user.”

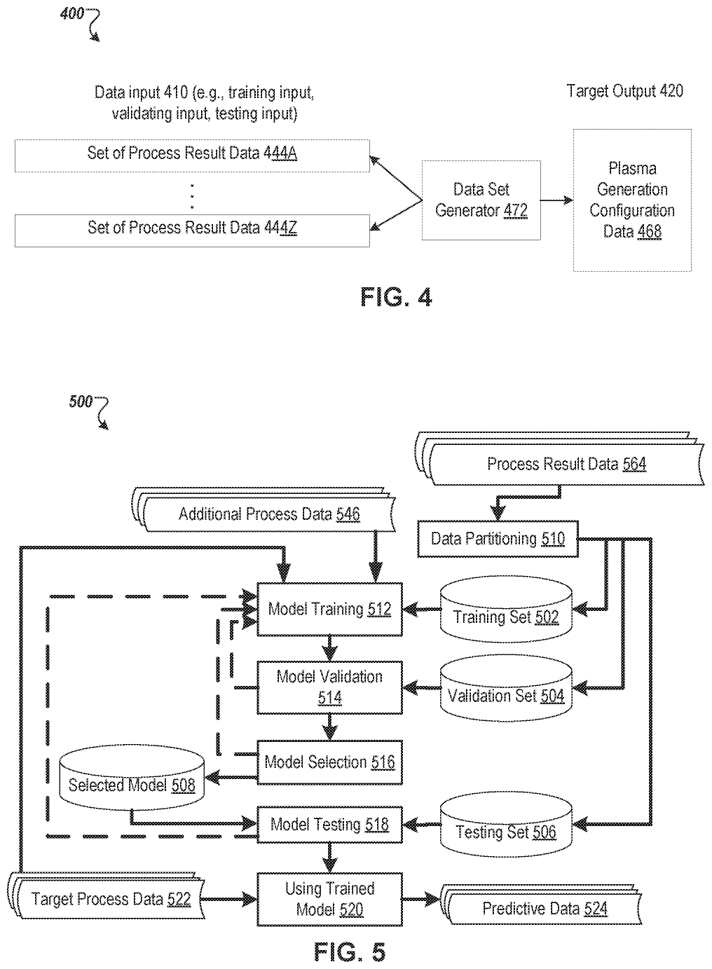

FIG. 4 depicts a block diagram of example data set generator 472 (e.g., data set generator 372 of FIG. 3) to create data sets for training, testing, validating, etc. a model (e.g., model 390 of FIG. 3), according to some embodiments. Data set generator 472 may be part of server machine 370 of FIG. 3. In some embodiments, several machine learning models associated with manufacturing equipment 324 may be trained, used, and maintained (e.g., within a manufacturing facility). Each machine learning model may be associated with one data set generators 472, multiple machine learning models may share a data set generator 472, etc.

FIG. 4 depicts a system 4 including data set generator 472 for creating data sets for one or more supervised models (e.g., model 390 of FIG. 3). Data set generator 472 may create data sets (e.g., data input 410, target output 420) using historical data. In some embodiments, a data set generator similar to data set generator 472 may be utilized to train an unsupervised machine learning model, e.g., target output 420 may not be generated by data set generator 472.

Data set generator 472 may generate data sets to train, test, and validate a model. In some embodiments, data set generator 472 may generate data sets for a machine learning model. In some embodiments, data set generator 472 may generate data sets for training, testing, and/or validating a model configured to generate predictive data. Data set generator 472 may generate data sets for a model configured to recommend plasma generation configurations. The machine learning model is provided with set of historical process result data 444A as data input 410. The machine learning model may be provided additional data sets, e.g., set of process result data 444Z. Multiple machine learning models may be provided different sets of data, e.g., set of process result data 444A may be provided to a first machine learning model, set of process result data 444Z may be provided to a second machine learning model, etc. The machine learning model may be configured to accept process result data as input data and generate predictive data and/or plasma generation configuration data as output.

Data set generator 472 may be used to generate data for any type of machine learning model that takes as input process result data. Data set generator 472 may be used to generate data for a machine learning model that generates predicted metrology data of a substrate. Data set generator 472 may be used to generate data for a machine learning model configured to provide process control instructions. Data set generator 472 may be used to generate data for a machine learning model configured to identify a product anomaly and/or processing equipment fault.

In some embodiments, data set generator 472 generates a data set (e.g., training set, validating set, testing set) that includes one or more data inputs 410 (e.g., training input, validating input, testing input). Data inputs 410 may be provided to training engine 382, validating engine 384, or testing engine 386 of FIG. 3. The data set may be used to train, validate, or test the model (e.g., model 390 of FIG. 3).

In some embodiments, data input 410 may include one or more sets of data. As an example, system 400 may produce sets of sensor data that may include one or more of metrology data from one or more types of metrology measurements, profile data from multiple locations of a substrate, combinations of metrology data from one or more types of metrology systems, patterns from process result data from one or more types of measurements, etc.

In some embodiments, data input 410 may include one or more sets of data. As an example, system 400 may produce sets of historical metrology data (e.g., process result data) that may include one or more of metrology data of a group of dimensions of a device (e.g., include height and width of the device but not optical data or surface roughness, etc.), metrology data derived from one or more types of sensors, combination of metrology data derived from one or more types of sensors, patterns from metrology data, etc. Sets of data input 410 may include data describing different aspects of manufacturing, e.g., a combination of metrology data and sensor data, a combination of metrology data and manufacturing parameters, combinations of some metrology data, some manufacturing parameter data and some sensor data, etc.

In some embodiments, data set generator 472 may generate a first data input corresponding to a first set of process result data 444A to train, validate, or test a first machine learning model. Data set generator 472 may generate a second data input corresponding to a second set of process result data 444Z to train, validate, or test a second machine learning model.

In some embodiments, data set generator 472 generates a data set (e.g., training set, validating set, testing set) that includes one or more data inputs 410 (e.g., training input, validating input, testing input) and may include one or more target outputs 420. Target outputs 420 may correspond to the data inputs 410. The data set may also include mapping data that maps the data inputs 410 to the target outputs 420. In some embodiments, data set generator 472 may generate data for training a machine learning model configured to output plasma generation configuration data, by generating data sets that include plasma generation configuration data 468 as target output 420.

Data inputs 210A may also be referred to as “features,” “attributes,” or “information.” In some embodiments, data set generator 472 may provide the data set to training engine 382, validating engine 384, or testing engine 386, where the data set is used to train, validate, or test the machine learning model (e.g., one of the machine learning models that are included in model 390, ensemble model 390, etc.).

FIG. 5 is a block diagram illustrating system 500 for generating output data (e.g., predictive data 348 of FIG. 3), according to some embodiments. In some embodiments, system 500 may be used in conjunction with a machine learning model configured to generate predictive data. System 500 may be used in conjunction with a machine learning model to determine a recommended plasma generation configuration. In some embodiments, system 500 may be used in conjunction with a machine learning model to determine a corrective action associated with manufacturing equipment. In some embodiments, system 500 may be used in conjunction with a machine learning model to determine a fault of manufacturing equipment. In some embodiments, system 500 may be used in conjunction with a machine learning model to cluster or classify substrates. System 500 may be used in conjunction with a machine learning model with a different function than those listed, associated with a manufacturing system.

At block 510, system 500 (e.g., components of predictive system 310 of FIG. 3) performs data partitioning (e.g., via data set generator 372 of server machine 370 of FIG. 3) of data to be used in training, validating, and/or testing a machine learning model. In some embodiments, process result data 564 includes historical data, such as historical metrology data, historical design data, historical classification data (e.g., classification of whether a product meets performance thresholds), historical microscopy image data, etc. Process result data 564 may include historical substrate profile data. Process result data 564 may undergo data partitioning at block 510 to generate training set 502, validation set 504, and testing set 506. For example, the training set may be 60% of the training data, the validation set may be 20% of the training data, and the testing set may be 20% of the training data.

The generation of training set 502, validation set 504, and testing set 506 may be tailored for a particular application. For example, the training set may be 60% of the training data, the validation set may be 20% of the training data, and the testing set may be 20% of the training data. System 500 may generate a plurality of sets of features for each of the training set, the validation set, and the testing set. For example, if training data 564 includes various types of metrology data, including features derived from data from 20 measurements that correspond to the same processing runs(s), the training data may be divided into a first set of features including measurements 1-10 and a second set of features including measurements 11-20. Either training input, target output, both, or neither may be divided into sets. Multiple models may be trained on different sets of data.

At block 512, system 500 performs model training (e.g., via training engine 382 of FIG. 3) using training set 502. Training of a machine learning model and/or of a physics-based model (e.g., a digital twin) may be achieved in a supervised learning manner, which involves providing a training dataset including labeled inputs through the model, observing its outputs, defining an error (by measuring the difference between the outputs and the label values), and using techniques such as deep gradient descent and backpropagation to tune the weights of the model such that the error is minimized. In many applications, repeating this process across the many labeled inputs in the training dataset yields a model that can produce correct output when presented with inputs that are different than the ones present in the training dataset. In some embodiments, training of a machine learning model may be achieved in an unsupervised manner, e.g., labels or classifications may not be supplied during training. An unsupervised model may be configured to perform anomaly detection, result clustering, etc.

For each training data item in the training dataset, the training data item may be input into the model (e.g., into the machine learning model). The model may then process the input training data item (e.g., a number of measured dimensions of a manufactured device, etc.) to generate an output. The output may include, for example, recommended plasma generation configuration data. The output may be compared to a label of the training data item (e.g., actual plasma generation configuration data associated with the process result provided as training input).

Processing logic may then compare the generated output to the label that was included in the training data item. Processing logic determines an error (i.e., a classification error) based on the differences between the output and the label(s). Processing logic adjusts one or more weights and/or values of the model based on the error.

In the case of training a neural network, an error term or delta may be determined for each node in the artificial neural network. Based on this error, the artificial neural network adjusts one or more of its parameters for one or more of its nodes (the weights for one or more inputs of a node). Parameters may be updated in a back propagation manner, such that nodes at a highest layer are updated first, followed by nodes at a next layer, and so on. An artificial neural network contains multiple layers of “neurons”, where each layer receives as input values from neurons at a previous layer. The parameters for each neuron include weights associated with the values that are received from each of the neurons at a previous layer. Accordingly, adjusting the parameters may include adjusting the weights assigned to each of the inputs for one or more neurons at one or more layers in the artificial neural network.

System 500 may train multiple models using multiple sets of features of the training set 502 (e.g., a first set of features of the training set 502, a second set of features of the training set 502, etc.). For example, system 500 may train a model to generate a first trained model using the first set of features in the training set (e.g., metrology measurements 1-10, etc.) and to generate a second trained model using the second set of features in the training set (e.g., metrology measurements 11-20, etc.). In some embodiments, the first trained model and the second trained model may be combined to generate a third trained model. The third combined model may be a better predictor than the first or the second trained model on its own. In some embodiments, sets of features used in comparing models may overlap (e.g., first set of features being metrology data from measurements 1-15 and second set of features being metrology data from measurements 5-20). In some embodiments, hundreds of models may be generated including models with various permutations of features and combinations of models.

At block 514, system 500 performs model validation (e.g., via validation engine 384 of FIG. 3) using the validation set 504. The system 500 may validate each of the trained models using a corresponding set of features of the validation set 504. For example, system 500 may validate the first trained model using the first set of features in the validation set (e.g., metrology measurements 1-10) and the second trained model using the second set of features in the validation set (e.g., metrology measurements 11-20). In some embodiments, system 500 may validate hundreds of models (e.g., models with various permutations of features, combinations of models, etc.) generated at block 512. At block 514, system 500 may determine an accuracy of each of the one or more trained models (e.g., via model validation) and may determine whether one or more of the trained models has an accuracy that meets a threshold accuracy. Responsive to determining that none of the trained models has an accuracy that meets a threshold accuracy, flow returns to block 512 where the system 500 performs model training using different sets of features of the training set. Responsive to determining that one or more of the trained models has an accuracy that meets a threshold accuracy, flow continues to block 516. System 500 may discard the trained models that have an accuracy that is below the threshold accuracy (e.g., based on the validation set).

At block 516, system 500 performs model selection (e.g., via selection engine 385 of FIG. 3) to determine which of the one or more trained models that meet the threshold accuracy has the highest accuracy (e.g., the selected model 508, based on the validating of block 514). Responsive to determining that two or more of the trained models that meet the threshold accuracy have the same accuracy, flow may return to block 512 where the system 500 performs model training using further refined training sets corresponding to further refined sets of features for determining a trained model that has the highest accuracy.

At block 518, system 500 performs model testing (e.g., via testing engine 386 of FIG. 3) using testing set 506 to test selected model 508. System 500 may test, using the first set of features in the testing set (e.g., metrology measurements 1-10), the first trained model to determine the first trained model meets a threshold accuracy (e.g., based on the first set of features of the testing set 506). Responsive to accuracy of the selected model 508 not meeting the threshold accuracy (e.g., the selected model 508 is overly fit to the training set 502 and/or validation set 504 and is not applicable to other data sets such as the testing set 506), flow continues to block 512 where system 500 performs model training (e.g., retraining) using different training sets corresponding to different sets of features (e.g., different process result data). Responsive to determining that selected model 508 has an accuracy that meets a threshold accuracy based on testing set 506, flow continues to block 520. In at least block 512, the model may learn patterns in the training data to make predictions recommended plasma generation configurations, and in block 518, the system 500 may apply the model on the remaining data (e.g., testing set 506) to test the predictions.

At block 520, system 500 uses the trained model (e.g., selected model 508) to receive target process data 522 (e.g., target process data 349 of FIG. 3) and determines (e.g., extracts), from the output of the trained model, predictive data 524. A corrective action associated with the manufacturing equipment 324 of FIG. 3 may be performed in view of predictive data 524. In some embodiments, target process data 522 may correspond to the same types of features in the historical data used to train the machine learning model. In some embodiments, target process data 522 corresponds to a subset of the types of features in historical data that are used to train selected model 508 (e.g., a machine learning model may be trained using a number of metrology measurements, and configured to generate output based on a subset of target metrology measurements).

In some embodiments, the performance of a machine learning model trained, validated, and tested by system 500 may deteriorate. For example, a manufacturing system associated with the trained machine learning model may undergo a gradual change or a sudden change. A change in the manufacturing system may result in decreased performance of the trained machine learning model. A new model may be generated to replace the machine learning model with decreased performance. The new model may be generated by altering the old model by retraining, by generating a new model, etc. Updating the machine learning model may be achieved by providing additional process data 546 for model training, model updating, model retraining, etc. Additional process data 546 may include similar features to process result data 564. Additional process data 546 may include data associated with target process data 522. For example, predictions of the trained model based on target process data 522 may be compared with measured results to provide additional process data for additional training of the model.

In some embodiments, one or more of the acts 510-520 may occur in various orders and/or with other acts not presented and described herein. In some embodiments, one or more of acts 510-520 may not be performed. For example, in some embodiments, one or more of data partitioning of block 510, model validation of block 514, model selection of block 516, or model testing of block 518 may not be performed.

FIG. 5 depicts a system configured for training, validating, testing, and using one or more machine learning models. The machine learning models are configured to accept data as input (e.g., target process result data, target metrology data, target substrate performance data, etc.) and provide data as output (e.g., predictive data, corrective action data, classification data, etc.). Partitioning, training, validating, selection, testing, and using blocks of system 500 may be executed similarly to train a second model, utilizing different types of data. Retraining may also be done, utilizing target process data 522 and/or additional process data 546.

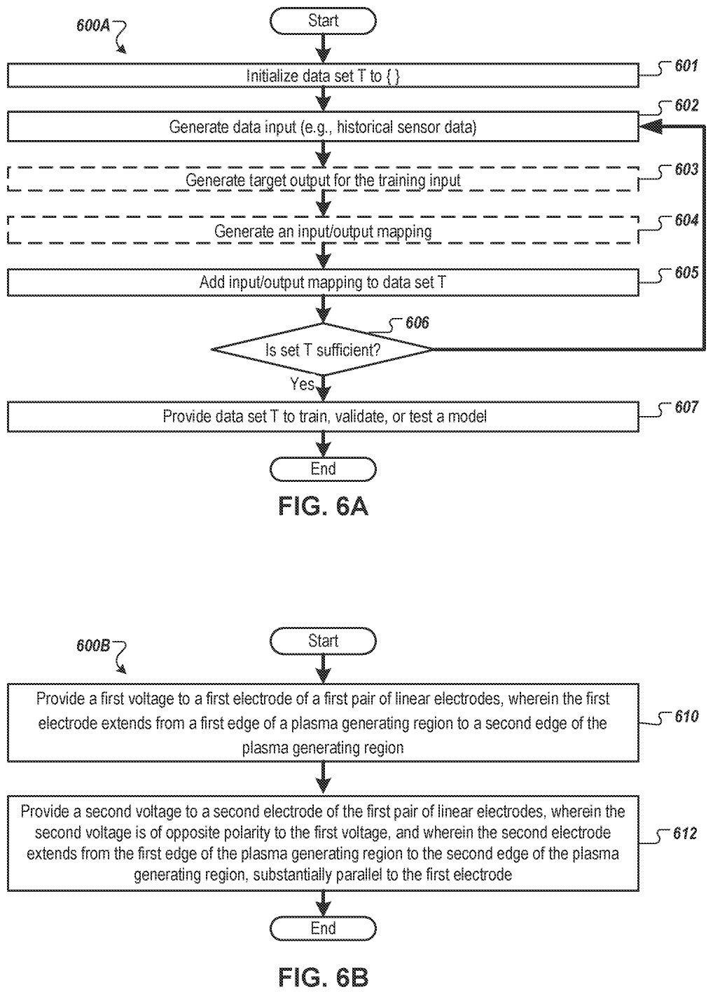

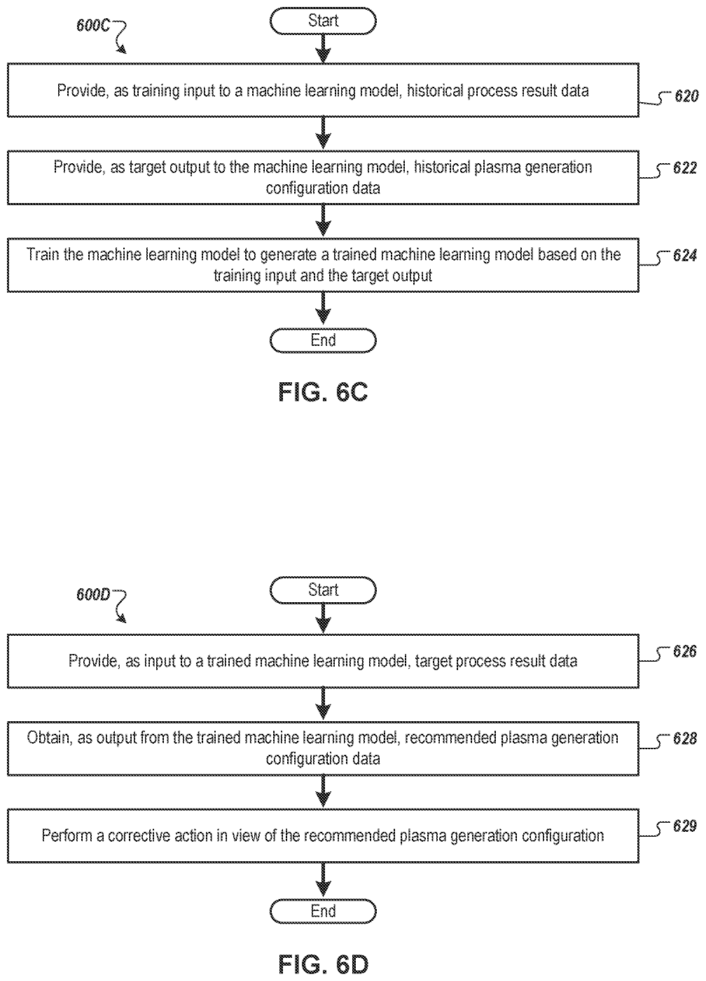

FIGS. 6A-C are flow diagrams of methods 600A-C associated with plasma generation, according to certain embodiments. Methods 600A-C may be performed by processing logic that may include hardware (e.g., circuitry, dedicated logic, programmable logic, microcode, processing device, etc.), software (such as instructions run on a processing device, a general purpose computer system, or a dedicated machine), firmware, microcode, or a combination thereof. In some embodiment, methods 600A-C may be performed, in part, by predictive system 310. Method 600A may be performed, in part, by predictive system 310 (e.g., server machine 370 and data set generator 372 of FIG. 3, data set generator 472 FIG. 4). Predictive system 310 may use method 600A to generate a data set to at least one of train, validate, or test a machine learning model, in accordance with embodiments of the disclosure. Methods 600B-C may be performed by predictive server 312 (e.g., predictive component 316) and/or server machine 380 (e.g., training, validating, and testing operations may be performed by server machine 380). Method 600B may be performed by a processing device associated with manufacturing equipment 324, e.g., a manufacturing control device, a recipe control device, etc. In some embodiments, a non-transitory machine-readable storage medium stores instructions that when executed by a processing device (e.g., of predictive system 310, of server machine 380, of predictive server 312, etc.) cause the processing device to perform one or more of methods 600A-C.

For simplicity of explanation, methods 600A-C are depicted and described as a series of operations. However, operations in accordance with this disclosure can occur in various orders and/or concurrently and with other operations not presented and described herein. Furthermore, not all illustrated operations may be performed to implement methods 600A-C in accordance with the disclosed subject matter. In addition, those skilled in the art will understand and appreciate that methods 600A-C could alternatively be represented as a series of interrelated states via a state diagram or events.

FIG. 6A is a flow diagram of a method 600A for generating a data set for a machine learning model, according to some embodiments. Referring to FIG. 6A, in some embodiments, at block 601 the processing logic implementing method 600A initializes a training set T to an empty set.

At block 602, processing logic generates first data input (e.g., first training input, first validating input) that may include one or more of sensor, manufacturing parameters, metrology data, etc. In some embodiments, the first data input may include a first set of features for types of data and a second data input may include a second set of features for types of data (e.g., as described with respect to FIG. 5). Input data may include process data in some embodiments. Input data may include historical process result data.

In some embodiments, at block 603, processing logic optionally generates a first target output for one or more of the data inputs (e.g., first data input). In some embodiments, the input includes one or more process results (e.g., metrology measurements) and the target output is a plasma generation configuration. In some embodiments, the first target output is predictive data. Predictive data may include predictions of results of utilizing a plasma generation configuration.

At block 604, processing logic optionally generates mapping data that is indicative of an input/output mapping. The input/output mapping (or mapping data) may refer to the data input (e.g., one or more of the data inputs described herein), the target output for the data input, and an association between the data input(s) and the target output. For example, process result data of a substrate may be mapped to plasma configuration data related to a plasma configuration used to process the substrate. In some embodiments, such as in association with machine learning models where no target output is provided, block 604 may not be executed.

At block 605, processing logic adds the mapping data generated at block 604 to data set T, in some embodiments.

At block 606, processing logic branches based on whether data set Tis sufficient for at least one of training, validating, and/or testing a machine learning model, such model 390 of FIG. 3. If so, execution proceeds to block 607, otherwise, execution continues back at block 602. It should be noted that in some embodiments, the sufficiency of data set T may be determined based simply on the number of inputs, mapped in some embodiments to outputs, in the data set, while in some other embodiments, the sufficiency of data set T may be determined based on one or more other criteria (e.g., a measure of diversity of the data examples, accuracy, etc.) in addition to, or instead of, the number of inputs.

At block 607, processing logic provides data set T (e.g., to server machine 380) to train, validate, and/or test machine learning model 390. In some embodiments, data set T is a training set and is provided to training engine 382 of server machine 380 to perform the training. In some embodiments, data set T is a validation set and is provided to validation engine 384 of server machine 380 to perform the validating. In some embodiments, data set T is a testing set and is provided to testing engine 386 of server machine 380 to perform the testing. In the case of a neural network, for example, input values of a given input/output mapping (e.g., numerical values associated with data inputs 410) are input to the neural network, and output values (e.g., numerical values associated with target outputs 420) of the input/output mapping are stored in the output nodes of the neural network. The connection weights in the neural network are then adjusted in accordance with a learning algorithm (e.g., back propagation, etc.), and the procedure is repeated for the other input/output mappings in data set T. After block 607, a model (e.g., model 390) can be at least one of trained using training engine 382 of server machine 380, validated using validating engine 384 of server machine 380, or tested using testing engine 386 of server machine 380. The trained model may be implemented by predictive component 316 (of predictive server 312) to generate predictive data 348 for performing signal processing, or for performing a corrective action associated with manufacturing equipment 324.

FIG. 6B is a flow diagram for a method 600B for generating plasma for substrate processing, according to some embodiments. At block 610, a first voltage is provided to a first electrode. The first electrode is one of a pair of linear electrodes. The first electrode extends from a first edge of a plasma generating region to a second edge of the plasma generating region.

At block 612, a second voltage is provided to a second electrode. The second electrode is the second electrode of the first pair of linear electrodes. The second voltage is of opposite polarity to the first voltage. The second electrode extends from the first edge of the plasma generating region to the second edge of the plasma generating region. The second electrode is substantially parallel to the first electrode.

In some embodiments, the first pair of electrodes comprises a plasma source. The first pair of electrodes may be part of a plasma generation component. The plasma generation component may include further plasma sources. The plasma generation component may include further pairs of electrodes. Electrodes of one or more further pairs of electrodes may be powered by the same power supply or power supplies as electrodes of the first pair of linear electrodes. A third electrode of a second pair of linear electrodes may be provided the first voltage. A fourth electrode of the second pair of linear electrodes may be provided the second voltage. The first and second voltages may be alternating voltages that are 180° out of phase.

In some embodiments, supplying power to the first pair of linear electrodes may be separable from supplying power to the second pair of linear electrodes. For example, there may be one or more switches that enable control one or more pairs of electrodes. In some embodiments, exposure of a substrate to plasma may be controlled by controlling an amount of time that at least one plasma source (e.g., pair of linear electrodes) is provided with power. Different pairs of linear electrodes may be associated with different zones of a substrate, e.g., a central zone, edge zone, intermediate zone.

In some embodiments, the first voltage may be provided to the first electrode via an electrical connection proximate the first edge of the plasma generating region. The second voltage may be provided to the second electrode via an electrical connection proximate the second edge of the plasma generating region.

In some embodiments, plasma may be provided to a substrate. The substrate may be caused to rotate, e.g., by supporting the substrate on a rotating stage. Plasma processing may further include providing a gas to the surface of the substrate. The gas may be a process gas, flush gas, cleaning gas, etc. The gas may be provided via channels through the plasma generation component that include the first pair of linear electrodes. Gas channels may be disposed between the first pair of linear electrodes and the second pair of linear electrodes.

FIG. 6C is a flow diagram of a method 600C for training a machine learning model to configure plasma generation, according to some embodiments. At block 620, processing logic provides data to a machine learning model. Processing logic provides historical process result data to the machine learning model as training input. Historical process result data may be or include metrology data of historical products. Historical process result data may be or include etch profiles of historical substrates.

At block 622, processing logic provides target output data to the machine learning model. The target output data includes historical plasma generation configuration data. The target output data may be associated with the training input data. The target output data may be or include plasma generation configurations used to process the products described by the historical process result data provided as training input. Plasma generation configurations may include selection of a plasma generation component for a target process procedure. Plasma generation configurations may include arrangement of electrodes into zones for a target procedure, operation, etc. Plasma generation configurations may include durations for providing power to various zones, sources, electrodes, etc. Plasma generation configurations may include recipes for frequency, power, voltage, etc., to provide to various sources, electrodes, etc.

At block 624, processing logic trains the machine learning model to generate a trained machine learning model. Training is performed based on the training input and the target output. Training is performed by providing the training input and the target output to the machine learning model. Training may be performed via a training engine. Producing the trained machine learning model may further include validating (e.g., via a validation engine), testing (e.g., via a testing engine), and/or model selection (e.g., via a selection engine).

The trained machine learning model may be configured to provide output data that may be used to configure plasma generation. The trained machine learning model may be configured to receive as input target process result data. The target process result data may include target metrology data, target etch depth data, target substrate profile data, etc. The trained machine learning model may be configured to provide one or more plasma generation configurations to generate a substrate with properties as provided by the input target process result data. The output may include plasma generation component selection, plasma source zone organization, plasma source and/or zone ON state and OFF state durations, data related to power provided to plasma sources, etc.

FIG. 6D is a flow diagram of a method 600D for using a trained machine learning model to configure plasma generation, according to some embodiments.

At block 626, processing logic provides, as input to the trained machine learning model, target process result data. The target process result data may include target substrate properties. The target process result data may include target substrate design. The target process result data may include target metrology data. The target process result data may include target substrate profile data.

At block 628, processing logic obtains, as output from the trained machine learning model, recommended plasma generation configuration data. The recommended plasma generation configuration data may be predicted to generate a substrate with properties of the target process result data. The recommended plasma generation configuration data may include recommended plasma generation component(s) for use in generating a substrate in accordance with target process results. The recommended plasma generation configuration data may include recommended plasma generation component operation instruction for use in generating a substrate in accordance with target process results.

At block 629, processing logic may further perform a corrective action in view of the output from the trained machine learning model. Corrective actions may include updating a process recipe, e.g., updating plasma generation configuration settings of a process recipe. Corrective actions may include updating a configuration of a plasma generation component, e.g., updating grouping of plasma sources of a component into zones. Corrective actions may include providing an alert to a user, e.g., recommended a user utilize a different plasma generation component of a set of plasma generation components.

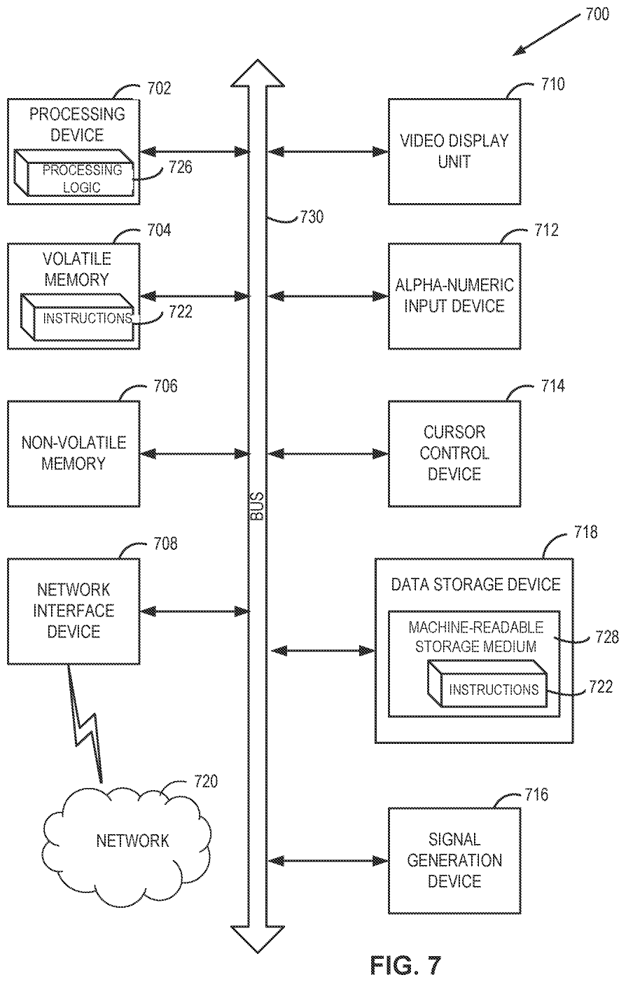

FIG. 7 depicts a block diagram of an example computing device 700 capable of operations associated with plasma delivery and/or processing, operating in accordance with one or more aspects of the disclosure. Computing device 700 may operate one or more machine learning models. Computing device 700 may provide control for one or more plasma sources of a plasma generation component. In various illustrative examples, various components of the computing device 700 may represent various components of computing device (e.g., predictive system 310 of FIG. 3), the training engine, validation engine, and/or the testing engine described in association with FIG. 3.

Example computing device 700 may be connected to other computer devices in a LAN, an intranet, an extranet, and/or the Internet. Computing device 700 may operate in the capacity of a server in a client-server network environment. Computing device 700 may be a personal computer (PC), a set-top box (STB), a server, a network router, switch or bridge, or any device capable of executing a set of instructions (sequential or otherwise) that specify actions to be taken by that device. Operations of computing device 700 may be enacted by cloud computing resources, e.g., cloud data storage, cloud data processing, etc. Further, while only a single example computing device is illustrated, the term “computer” shall also be taken to include any collection of computers that individually or jointly execute a set (or multiple sets) of instructions to perform any one or more of the methods discussed herein.

Example computing device 700 may include a processing device 702 (also referred to as a processor or CPU), a main memory 704 (e.g., read-only memory (ROM), flash memory, dynamic random access memory (DRAM) such as synchronous DRAM (SDRAM), etc.), a static (non-volatile) memory 706 (e.g., flash memory, static random access memory (SRAM), etc.), and a secondary memory (e.g., a data storage device 718), which may communicate with each other via a bus 730.

Processing device 702 represents one or more general-purpose processing devices such as a microprocessor, central processing unit, or the like. More particularly, processing device 702 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processing device 702 may also be one or more special-purpose processing devices such as an application specific integrated circuit (ASIC), a field programmable gate array (FPGA), a digital signal processor (DSP), network processor, or the like. In accordance with one or more aspects of the disclosure, processing device 702 may be configured to execute instructions implementing methods 600A-600C illustrated in FIGS. 6A-C.

Example computing device 700 may further comprise a network interface device 708, which may be communicatively coupled to a network 720. Example computing device 700 may further comprise a video display 710 (e.g., a liquid crystal display (LCD), a touch screen, or a cathode ray tube (CRT)), an alphanumeric input device 712 (e.g., a keyboard), a cursor control device 714 (e.g., a mouse), and a signal generation device 716 (e.g., a speaker).

Data storage device 718 may include a machine-readable storage medium (or, more specifically, a non-transitory machine-readable storage medium) 728 on which is stored one or more sets of executable instructions 722. In accordance with one or more aspects of the disclosure, executable instructions 722 may comprise executable instructions associated with executing methods 600A-600C of FIGS. 6A-C.

Executable instructions 722 may also reside, completely or at least partially, within main memory 704 and/or within processing device 702 during execution thereof by example computing device 700, main memory 704 and processing device 702 also constituting computer-readable storage media. Executable instructions 722 may further be transmitted or received over a network via network interface device 708. Executable instructions may be stored, in part or in full, by a processing device 702. Executable instructions may be enacted by processing logic 726.

While the computer-readable storage medium 728 is shown in FIG. 7 as a single medium, the term “computer-readable storage medium” should be taken to include a single medium or multiple media (e.g., a centralized or distributed database, and/or associated caches and servers) that store the one or more sets of operating instructions. The term “computer-readable storage medium” shall also be taken to include any medium that is capable of storing or encoding a set of instructions for execution by the machine that cause the machine to perform any one or more of the methods described herein. The term “computer-readable storage medium” shall accordingly be taken to include, but not be limited to, solid-state memories, and optical and magnetic media.

Some portions of the detailed descriptions above are presented in terms of algorithms and symbolic representations of operations on data bits within a computer memory. These algorithmic descriptions and representations are the means used by those skilled in the data processing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise, as apparent from the following discussion, it is appreciated that throughout the description, discussions utilizing terms such as “identifying,” “determining,” “storing,” “adjusting,” “causing,” “returning,” “comparing,” “creating,” “stopping,” “loading,” “copying,” “throwing,” “replacing,” “performing,” obtaining,” or the like, may refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Examples of the disclosure also relate to an apparatus for performing the methods described herein. This apparatus may be specially constructed for the required purposes, or it may be a general-purpose computer system selectively programmed by a computer program stored in the computer system. Such a computer program may be stored in a computer readable storage medium, such as, but not limited to, any type of disk including optical disks, compact disc read only memory (CD-ROMs), and magnetic-optical disks, read-only memories (ROMs), random access memories (RAMs), erasable programmable read-only memory (EPROMs), electrically erasable programmable read-only memory (EEPROMs), magnetic disk storage media, optical storage media, flash memory devices, other type of machine-accessible storage media, or any type of media suitable for storing electronic instructions, each coupled to a computer system bus.

The methods and displays presented herein are not inherently related to any particular computer or other apparatus. Various general-purpose systems may be used with programs in accordance with the teachings herein, or it may prove convenient to construct a more specialized apparatus to perform the required method steps. The required structure for a variety of these systems will appear as set forth in the description below. In addition, the scope of the disclosure is not limited to any particular programming language. It will be appreciated that a variety of programming languages may be used to implement the teachings of the disclosure.

The preceding description sets forth numerous specific details such as examples of specific systems, components, methods, and so forth, in order to provide a good understanding of several embodiments of the disclosure. It will be apparent to one skilled in the art, however, that at least some embodiments of the disclosure may be practiced without these specific details. In other instances, well-known components or methods are not described in detail or are presented in simple block diagram format in order to avoid unnecessarily obscuring the disclosure. Thus, the specific details set forth are merely exemplary. Particular implementations may vary from these exemplary details and still be contemplated to be within the scope of the disclosure.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It is to be understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

1. A plasma generating component for a process chamber, comprising:
an array of substantially parallel linear plasma sources, wherein each linear plasma source comprises a pair of linear substantially parallel electrodes, and wherein each electrode extends from a first edge of a plasma generating region of the plasma generating component to a second edge, opposite the first edge, of the plasma generating region;
a dielectric support to which electrodes of the array of substantially parallel linear plasma sources are secured; and
a dielectric material disposed opposite the dielectric support with respect to the array of substantially parallel linear plasma sources.

2. The plasma generating component of claim 1, wherein a first electrode of each pair of linear substantially parallel electrodes is electrically coupled to a first terminal of a power supply, and a second electrode of each pair of linear substantially parallel electrodes is electrically coupled to a second terminal of the power supply.

3. The plasma generating component of claim 2, wherein the first electrode of each pair of linear substantially parallel electrodes is electrically coupled to the first terminal proximate the first edge of the plasma generating region, and wherein the second electrode of each pair of linear substantially parallel electrodes is electrically coupled to the second terminal of the power supply proximate the second edge of the plasma generating region.

4. The plasma generating component of claim 2, wherein a first electrode of a first pair of linear substantially parallel electrodes is adjacent a second electrode of a second pair of linear substantially parallel electrodes, and wherein the first electrode of the first pair of linear substantially parallel electrodes is electrically coupled to the first terminal of the power supply, and the second electrode of the second pair of linear substantially parallel electrodes is electrically coupled to the first terminal of the power supply.

5. The plasma generating component of claim 1, wherein a first plurality of substantially parallel linear plasma sources are electrically coupled together, and electrically decoupled from a linear plasma source of the plasma generating component that is not of the first plurality of substantially parallel linear plasma sources.

6. The plasma generating component of claim 1, wherein a power supply is electrically coupled to a first linear plasma source of the array of substantially parallel linear plasma sources and a second linear plasma source of the array of substantially parallel linear plasma sources; and wherein the power supply is configured to provide power to the first linear plasma source for a first duration, and to provide power to the second linear plasma source for a second duration, different from the first duration.

7. The plasma generating component of claim 6, wherein a first plurality of linear plasma sources comprises the first plasma source, and is disposed proximate an edge of the plasma generating region, and wherein a second plurality of linear plasma sources comprises the second plasma source, and is disposed to intersect a central area of the plasma generating region.

8. The plasma generating component of claim 1, further comprising:
a first gas inlet disposed on a first side of the plasma generating component; and
a first plurality of gas outlets, fluidly coupled to the gas inlet, disposed on a second side of the plasma generating component, opposite the first side.

9. The plasma generating component of claim 8, further comprising a second gas inlet fluidly coupled to a second plurality of gas outlets, wherein the first plurality of gas outlets are disposed in a first gas delivery zone, and the second plurality of gas outlets are disposed in a second gas delivery zone.

10. A method comprising generating a plasma for substrate processing, wherein generating the plasma comprises:
providing a first voltage to a first electrode of a first pair of linear electrodes, wherein the first electrode of the first pair of linear electrodes extends from a first edge of a plasma generating region to a second edge of the plasma generating region; and
providing a second voltage to a second electrode of the first pair of linear electrodes, wherein the second voltage is of opposite polarity to the first voltage, and wherein the second electrode of the first pair of linear electrodes extends from the first edge of the plasma generating region to the second edge of the plasma generating region, substantially parallel to the first electrode of the first pair of linear electrodes.

11. The method of claim 10, wherein generating the plasma further comprises:
providing the first voltage to a first electrode of a second pair of linear electrodes, wherein the first electrode of the second pair of linear electrodes is substantially parallel to the first electrode of the first pair of linear electrodes; and
providing the second voltage to a second electrode of the second pair of linear electrodes.

12. The method of claim 11, wherein generating the plasma further comprises:
for a first duration of time, providing the first voltage to the first electrode of the second pair of linear electrodes and providing the second voltage to the second electrode of the second pair of linear electrodes; and
for a second duration of time, electrically decoupling the first electrode of the second pair of electrodes and the second electrodes of the second pair of electrodes from a source of the first voltage and the second voltage.

13. The method of claim 12, wherein the first pair of linear electrodes intersects a central area of the plasma generating region; and wherein the second pair of linear electrodes does not intersect the central area of the plasma generating region.

14. The method of claim 12, further comprising:
providing a target substrate profile to a trained machine learning model; and
receiving output from the trained machine learning model, wherein a length of the first duration of time and a length of the second duration of time are determined based on the output from the trained machine learning model.

15. The method of claim 10, wherein the first electrode is electrically coupled to a supply providing the first voltage proximate the first edge of the plasma generating region, and the second electrode is electrically coupled to a supply providing the second voltage proximate the second edge of the plasma generating region.

16. The method of claim 10, further comprising causing rotation of a substrate that is interacting with the plasma relative to the first pair of linear electrodes.

17. The method of claim 10, further comprising providing a process gas to a surface of a substrate by causing gas to flow through a plurality of channels disposed between the first electrode and the second electrode, wherein a gas pressure in the plasma generating region is maintained between 1 torr and 100 torr during plasma generation procedures.

18. The method of claim 10, wherein, responsive to providing the first voltage and the second voltage to the first electrode of the first pair of linear electrodes and the second electrode of the first pair of linear electrodes, the first pair of linear electrodes causes a first exposure of a substrate to plasma, and wherein a second pair of linear electrodes causes a second exposure of the substrate to plasma, the second exposure being different than the first exposure by adjusting one or more of:
a duration that a voltage is provided to the second pair of linear electrodes compared to a duration that the first voltage is provided to the first electrode of the first pair of linear electrodes;
a frequency with which the voltage is provided to the second pair of linear electrodes compared to a frequency that the first voltage is provided to the first electrode of the first pair of linear electrodes; or
a value of the voltage provided to the second pair of linear electrodes compared to the first voltage that is provided to the first electrode of the first pair of linear electrodes.

19. A method, comprising:
providing, as input to a trained machine learning model, target process result data;
obtaining, as output from the trained machine learning model, recommended plasma generation configuration data; and
performing a corrective action in view of the recommended plasma generation configuration data.

20. The method of claim 19, further comprising:
providing, as training input to a machine learning model, historical process result data;
providing, as target output to the machine learning model, historical plasma generation configuration data; and
training the machine learning model to generate the trained machine learning model based on the training input and the target output.
